(19) United States
(12) Patent Application Publication
(10) Pub. No.: US 2026/0293394 A1
(43) Pub. Date: Sep. 24, 2026

(54) MICRO-LED DISPLAY CHIP AND MANUFACTURING METHOD THEREFOR

(71) Applicant: Raysolve Optoelectronics (Suzhou) Company Limited, Suzhou (CN)

(72) Inventors: Xu ZHANG, Suzhou (CN); Wing Cheung CHONG, Suzhou (CN)

(73) Assignee: Raysolve Optoelectronics (Suzhou) Company Limited, Suzhou (CN)

(21) Appl. No.: 19/685,492

(22) Filed: May 22, 2026

Related U.S. Application Data
(63) Continuation of application No. PCT/CN2024/132861, filed on Nov. 19, 2024.

(30) Foreign Application Priority Data
Nov. 24, 2023 (CN) 202311577508.3

(51) Int. Cl. H10H 29/32; H10H 20/813; H10H 29/01; H10H 29/45; H10H 29/49; H10H 29/85; H10H 29/856

(52) U.S. Cl. CPC H10H 29/32; H10H 20/8131; H10H 29/012; H10H 29/0363; H10H 29/49; H10H 29/45; H10H 29/8517; H10H 29/856

(57) ABSTRACT

A Micro-LED display chip includes a driving substrate, a plurality of Micro-LED elements, and a plurality of filter elements, the plurality of Micro-LED elements and the plurality of filter elements are located on one side of the driving substrate. Each Micro-LED element includes at least two light emitting structure layers, the at least two light emitting structure layers are stacked in a direction perpendicular to the driving substrate, and the at least two light emitting structure layers are connected in series, so that when the driving substrate independently drives the Micro-LED element, the at least two light emitting structure layers in the Micro-LED element synchronously emit light. The plurality of filter elements and the plurality of Micro-LED elements are correspondingly arranged, and each filter element of the plurality of filter elements is at least arranged above a light-emitting surface of a corresponding Micro-LED element.

### CROSS-REFERENCE TO RELATED APPLICATIONS

The present application is a continuation application of International Application No. PCT/CN2024/132861, filed on Nov. 19, 2024, which claims priority to Chinese Patent Application No. 202311577508.3, filed on Nov. 24, 2023. All of the aforementioned patent applications are hereby incorporated by reference in their entireties.

### TECHNICAL FIELD

The present application relates to the field of micro display technology, and specifically to a Micro Light Emitting Diode (Micro-LED) display chip and a manufacturing method therefor.

### BACKGROUND

A Micro-LED display chip is a two-dimensional array display device that integrates high-density pixel light-emitting units on a chip. The Micro-LED display chips are widely used in fields such as Augmented Reality (AR), near-eye display (NED) and wearable displays due to advantages of small size, long life, fast response speed and low power consumption.

Although color display of the Micro-LED display chips can currently be achieved by using wavelength conversion elements to convert the excitation light emitted by the Micro-LED elements into the stimulated light of different wavelengths, the light emitting efficiency and life of the Micro-LED display chip are limited by the conversion efficiency and life of the wavelength conversion elements, thereby preventing further improvement of the light emitting efficiency and life of the Micro-LED display chip.

### SUMMARY

The present application discloses a Micro-LED display chip and a manufacturing method therefor, to improve the light emitting efficiency and life of the Micro-LED display chip.

In a first aspect, a Micro-LED display chip is disclosed by the present application. The Micro-LED display chip includes a driving substrate, a plurality of Micro-LED elements and a plurality of filter elements, the plurality of Micro-LED elements and the plurality of filter elements are located on one side of the driving substrate, the plurality of Micro-LED elements are arranged at intervals, and each Micro-LED element of the plurality of Micro-LED elements includes at least two light emitting structure layers, the at least two light emitting structure layers include a first light emitting structure layer for emitting a first color light and a second light emitting structure layer for emitting a second color light, the at least two light emitting structure layers are stacked in a direction perpendicular to the driving substrate, and the at least two light emitting structure layers are connected in series, so that when the driving substrate independently drives the Micro-LED element, the at least two light emitting structure layers in the Micro-LED element synchronously emit light, and the plurality of filter elements and the plurality of Micro-LED elements are correspondingly arranged, each filter element of the plurality of filter elements is at least arranged above a light-emitting surface of the corresponding Micro-LED element, the plurality of filter elements at least include a first filter element and a second filter element, the first filter element transmits the first color light and filters out other color lights except the first color light, and the second filter element transmits the second color light and filters out other color lights except the second color light.

In some optional examples, the driving substrate includes a plurality of first contacts and a plurality of second contacts, the plurality of first contacts are respectively located between respective adjacent ones of the plurality of Micro-LED elements, and the plurality of second contacts are respectively located below the plurality of Micro-LED elements, in the Micro-LED element, any two adjacent light emitting structure layers of the at least two light emitting structure layers are electrically connected, in the Micro-LED element, the light emitting structure layer that is the farthest from the driving substrate is in correspondence with the first contact and electrically connected to the first contact corresponding to the light emitting structure layer, in the Micro-LED element, the light emitting structure layer that is the closest to the driving substrate is in correspondence with the second contact and electrically connected to the second contact corresponding to the light emitting structure layer.

In some optional examples, each light emitting structure layer of the at least two light emitting structure layers includes a first doping type semiconductor layer, a light-emitting layer and a second doping type semiconductor layer that are stacked, in any two adjacent light emitting structure layers of the at least two light emitting structure layers of the Micro-LED element, the first doping type semiconductor layer of one light emitting structure layer is electrically connected to the second doping type semiconductor layer of another light emitting structure layer adjacent to the one light emitting structure layer, to achieve a series connection between the two adjacent light emitting structure layers, in the Micro-LED element, the first doping type semiconductor layer of the light emitting structure layer that is the farthest from the driving substrate is in correspondence with the first contact and electrically connected to the first contact corresponding to the first doping type semiconductor layer, and the second doping type semiconductor layer of the light emitting structure layer that is the closest to the driving substrate is in correspondence with the second contact and electrically connected to the second contact corresponding to the second doping type semiconductor layer.

In some optional examples, the Micro-LED element further includes a bonding layer, the bonding layer includes at least one first bonding layer and one second bonding layer, the first bonding layer is located between any two adjacent light emitting structure layers of the at least two light emitting structure layers, and the first bonding layer is used for bonding and electrically connecting the two adjacent light emitting structure layers, the second bonding layer is located between the light emitting structure layer that is the closest to the driving substrate and the driving substrate, and the second bonding layer is used for bonding the light emitting structure layer that is the closest to the driving substrate to the driving substrate and electrically connecting the light emitting structure layer that is the closest to the driving substrate to the second contact of the driving substrate.

In some optional examples, material of the first bonding layer includes transparent conductive material, so as to allow light emitted by the at least two light emitting structure layers to pass through, and material of the second bonding layer includes reflective conductive material to reflect light emitted by the at least two light emitting structure layers.

In some optional examples, the Micro-LED display chip further includes a passivation layer, a light-emitting surface and a side surface of the Micro-LED element are covered by the passivation layer, the passivation layer includes a plurality of first openings and a plurality of second openings, the plurality of first openings respectively expose a plurality of first connection portions of the plurality of Micro-LED elements, the first connection portion is the light emitting structure layer that is the farthest from the driving substrate in the Micro-LED element, and the plurality of second openings respectively expose the plurality of first contacts of the driving substrate.

In some optional examples, the Micro-LED display chip further includes a plurality of first electrodes, the plurality of first electrodes and the plurality of Micro-LED elements are correspondingly arranged, and each first electrode of the plurality of first electrodes is used to electrically connect the first connection portion of the Micro-LED element to the first contact corresponding to the Micro-LED element through the first opening and the second opening corresponding to the Micro-LED element.

In some optional examples, the Micro-LED display chip further includes an etch stop layer, the etch stop layer is located on a side, away from the driving substrate, of the passivation layer or the first electrode, and the light-emitting surface and the side surface of the Micro-LED element are covered by the etch stop layer.

In some optional examples, the Micro-LED display chip further includes a light-blocking wall, the light-blocking wall is located between two adjacent Micro-LED elements of the plurality of Micro-LED elements, a side wall of the light-blocking wall is disposed on a reflective layer, and the reflective layer reflects light emitted by the Micro-LED element.

In some optional examples, a planarization layer is located between the filter element and the Micro-LED element corresponding to the filter element, and light emitted by the Micro-LED element is allowed to pass through the planarization layer.

In some optional examples, the at least two light emitting structure layers further include a third light emitting structure layer capable of emitting a third color light, and the plurality of filter elements further include a third filter element, the third filter element transmits the third color light and filters out other color lights except the third color light.

In some optional examples, the Micro-LED display chip further includes a plurality of micro-lenses, the plurality of micro-lenses and the plurality of Micro-LED elements are correspondingly arranged, and each micro-lens of the plurality of micro-lenses is used for converging and/or collimating light emitted by the corresponding Micro-LED.

In a second aspect, the present application discloses a manufacturing method for a Micro-LED display chip, including: forming, on one side of a driving substrate, at least two light emitting structure layers being stacked in a direction perpendicular to the driving substrate, connecting the at least two light emitting structure layers in series, where the at least two light emitting structure layers include a first light emitting structure layer for emitting a first color light and a second light emitting structure layer for emitting a second color light; etching the at least two light emitting structure layers, to form a plurality of Micro-LED elements arranged at intervals by the at least two light emitting structure layers, when the driving substrate independently drives each Micro-LED element of the plurality of Micro-LED elements, the at least two light emitting structure layers in the Micro-LED element synchronously emit light; forming a plurality of filter elements on one side of the driving substrate, the plurality of filter elements and the plurality of Micro-LED elements are correspondingly arranged, and each filter element of the plurality of filter elements is at least arranged above the corresponding Micro-LED element, the plurality of filter elements at least include a first filter element and a second filter element, the first filter element transmits the first color light and filters out other color lights except the first color light, and the second filter element transmits the second color light and filters out other color lights except the second color light.

In some optional examples, the forming, on one side of a driving substrate, at least two light emitting structure layers being stacked in a direction perpendicular to the driving substrate including: disposing the first light emitting structure layer on a first substrate, where the first light emitting structure layer includes a first doping type semiconductor layer, a light-emitting layer and a second doping type semiconductor layer that are stacked; disposing the second light emitting structure layer on a second substrate, where the second light emitting structure layer includes a first doping type semiconductor layer, a light-emitting layer and a second doping type semiconductor layer that are stacked; bonding the first light emitting structure layer to the driving substrate via a second bonding layer, and electrically connecting the second doping type semiconductor layer of the first light emitting structure layer to the second contact corresponding to the driving substrate; removing the first substrate and exposing the first doping type semiconductor layer of the first light emitting structure layer; bonding the first light emitting structure layer to the second light emitting structure layer via a first bonding layer, such that the first doping type semiconductor layer of the first light emitting structure layer is electrically connected to the second doping type semiconductor layer of the second light emitting structure layer, to achieve a series connection between the two adjacent light emitting structure layers of the at least two light emitting structure layers; and removing the second substrate and exposing the first doping type semiconductor layer of the second light emitting structure layer.

In some optional examples, the manufacturing method further includes: disposing a third light emitting structure layer for emitting a third color light on a third substrate, where the third light emitting structure layer includes a first doping type semiconductor layer, a light-emitting layer and a second doping type semiconductor layer that are stacked; bonding the third light emitting structure layer to the second light emitting structure layer via the first bonding layer, and electrically connecting the first doping type semiconductor layer of the second light emitting structure layer to the second doping type semiconductor layer of the third light emitting structure layer, to achieve a series connection between the two adjacent light emitting structure layers of the at least two light emitting structure layers; removing the third substrate and exposing the first doping type semiconductor layer of the third light emitting structure layer, where the plurality of filter elements further include a third filter element, the third filter element transmits the third color light and filters out other color lights except the third color light.

In some optional examples, after the etching the at least two light emitting structure layers to form a plurality of Micro-LED elements arranged at intervals by the at least two light emitting structure layers, the manufacturing method further includes forming, on one side of the driving substrate, a passivation layer covering a light-emitting surface and a side surface of the Micro-LED element, where the passivation layer includes a plurality of first openings and a plurality of second openings, the plurality of first openings respectively expose a plurality of first connection portions of the plurality of Micro-LED elements, the first connection portion is the light emitting structure layer that is the farthest from the driving substrate in the Micro-LED element, the plurality of second openings respectively expose a plurality of first contacts of the driving substrate; and forming a plurality of first electrodes on one side of the driving substrate, where the plurality of first electrodes and the plurality of Micro-LED elements are correspondingly arranged, such that each first electrode of the plurality of first electrodes is used to electrically connect the first connection portion of the Micro-LED element to the first contact corresponding to the Micro-LED element through the first opening and the second opening corresponding to the Micro-LED element.

In some optional examples, the manufacturing method further includes forming an etch stop layer on one side of the driving substrate, such that the etch stop layer is located on a side, away from the driving substrate, of the passivation layer or the first electrode, and the light-emitting surface and the side surface of the Micro-LED element are covered by the etch stop layer.

In some optional examples, before the forming the plurality of filter elements on one side of the driving substrate, the manufacturing method further includes forming a light-blocking wall on one side of the driving substrate, the light-blocking wall is located between respective adjacent ones of the plurality of Micro-LED elements; and forming a reflective layer at a side wall, towards the Micro-LED element, of the light-blocking wall, where the reflective layer reflects light emitted by the Micro-LED element.

In some optional examples, the manufacturing method further includes forming a planarization layer on one side of the driving substrate, such that the planarization layer covers the Micro-LED element and fills a groove surrounded by the light-blocking wall, and light emitted by the Micro-LED element is allowed to pass through the planarization layer.

In some optional examples, the manufacturing method further includes forming a plurality of micro-lenses on one side of the driving substrate, where the plurality of Micro-LED elements and the plurality of micro-lenses are correspondingly arranged, and each micro-lens of the plurality of micro-lenses converges and/or collimates light emitted by the corresponding Micro-LED element.

The Micro-LED display chip and the manufacturing method therefor disclosed by the present application include a driving substrate, a plurality of Micro-LED elements and a plurality of filter elements, the plurality of Micro-LED elements and the plurality of filter elements are located on one side of the driving substrate, the plurality of Micro-LED elements are arranged at intervals, and each Micro-LED element includes at least two light emitting structure layers. The at least two light emitting structure layers are arranged in a stacked arrangement in a direction perpendicular to the driving substrate, and the at least two light emitting structure layers are connected in series, so that when the driving substrate independently drives the Micro-LED element, the at least two light emitting structure layers in the Micro-LED element synchronously emit light, and the plurality of filter elements and the plurality of Micro-LED elements are correspondingly arranged, each filter element of the plurality of filter elements is at least arranged above a light-emitting surface of the corresponding Micro-LED element, the plurality of filter elements at least include a first filter element and a second filter element, the first filter element transmits the first color light and filters out other color lights except the first color light, and the second filter element transmits the second color light and filters out other color lights except the second color light. Based on this, at least the first light emitting structure layer and the second light emitting structure layer are connected in series, the first light emitting structure layer can emit the first color light and second light emitting structure layer can emit the second color light, and at least the first filter element and the second filter element can respectively transmit the first color light and the second color light for color display, there is no need to adopt wavelength conversion elements for wavelength conversion, thereby improving the light emitting efficiency, light emitting brightness and life of the Micro-LED display chip.

### BRIEF DESCRIPTION OF THE DRAWINGS

To more clearly illustrate the technical solutions in the embodiments or the background art of the present application, the drawings required for use in the embodiments or the background art of the present application will be described below.

FIG. 1 is a schematic cross-sectional structural view of a conventional Micro-LED display chip.

FIG. 2 is a schematic cross-sectional structural view of a Micro-LED display chip disclosed in an embodiment of the present application.

FIG. 3 is a schematic cross-sectional structural view of a Micro-LED element disclosed in an embodiment of the present application.

FIG. 4 is a schematic cross-sectional structural view of a Micro-LED element disclosed in another embodiment of the present application.

FIG. 5 is a partial cross-sectional structural view of a Micro-LED element in the Micro-LED display chip shown in FIG. 2.

FIG. 6 is another partial cross-sectional structural view of a Micro-LED element in the Micro-LED display chip shown in FIG. 2.

FIG. 7 is a schematic cross-sectional structural view of a Micro-LED element disclosed in another embodiment of the present application.

FIG. 8 is a schematic flowchart of a manufacturing method for a Micro-LED display chip disclosed in an embodiment of the present application.

FIG. 9 to 23 are schematic cross-sectional structural views of various process steps in a manufacturing method for a Micro-LED display chip disclosed in an embodiment of the present application.

### DETAILED DESCRIPTIONS OF THE EMBODIMENTS

The technical solutions in the embodiments of the present application will be clearly and completely described below with reference to the accompanying drawings in the embodiments of the present application. Obviously, the described embodiments are only a part of the embodiments of the present application, not all of the embodiments. Based on the embodiments in the present application, all other embodiments obtained by a person of ordinary skill in the art without creative efforts fall within the scope of protection of the present application.

A Micro-LED display chip includes a Micro-LED array, the Micro-LED array is a high-density integrated LED array with a micron-scale spacing. Furthermore, each Micro-LED element in the Micro-LED array, serving as a pixel point, can be individually addressed and turned on, so that the Micro-LED array displays a corresponding image.

However, currently, most Micro-LED display chips achieve color display by using wavelength conversion elements to convert the excitation light emitted by the Micro-LED elements into stimulated light with different wavelengths. As shown in FIG. 1, the red wavelength conversion element can be excited by blue light to generate red light, and the green wavelength conversion element can be excited by blue light to generate green light, and color display is achieved by a mixed light of red light, green light and blue light. However, because the conversion efficiency and life of the wavelength conversion elements 02 are relatively low, the light emitting efficiency and life of the Micro-LED display chip are relatively low.

Based on this, the present application provides a display solution. By forming at least two light emitting structure layers that are stacked and in series connection in a Micro-LED element, the at least two light emitting structure layers respectively emit light of at least two colors, and at least two filter elements respectively transmit the light of at least two colors for color display, thereby improving the light emitting efficiency and life of the Micro-LED display chip.

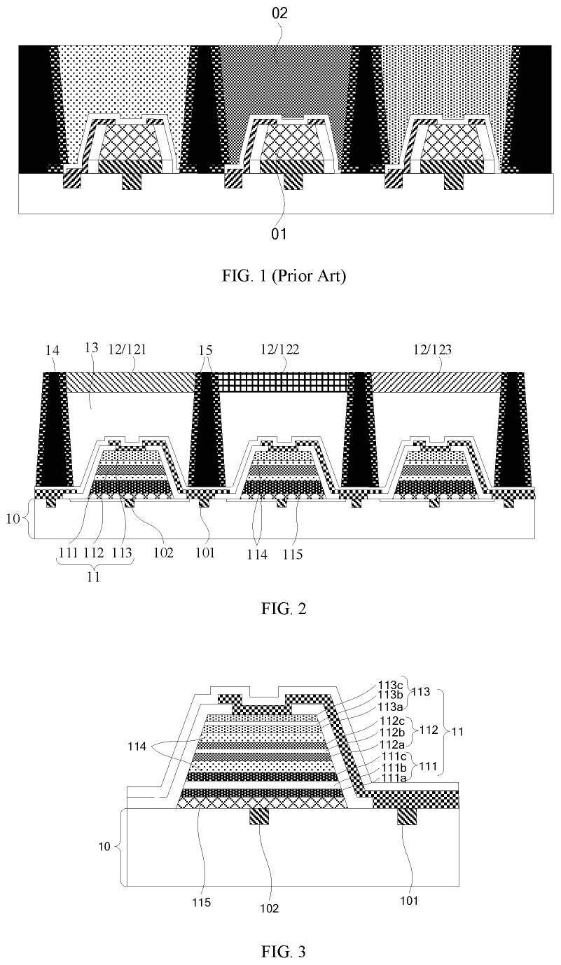

As an optional implementation of the disclosure of the present application, the Micro-LED display chip is disclosed in an embodiment of the present application. As shown in FIG. 2, the Micro-LED display chip includes a driving substrate 10, a plurality of Micro-LED elements 11 and a plurality of filter elements 12, the plurality of Micro-LED elements 11 and the plurality of filter elements 12 are located on one side of the driving substrate 10.

The plurality of Micro-LED elements 11 are arranged at intervals, and each Micro-LED element 11 includes at least two light emitting structure layers, the at least two light emitting structure layers may respectively emit light of at least two colors. In some embodiments of the present application, as shown in FIG. 2, the Micro-LED element 11 includes a first light emitting structure layer 111, a second light emitting structure layer 112 and a third light emitting structure layer 113. The first light emitting structure layer 111 may emit a first color light, the second light emitting structure layer 112 may emit a second color light, and the third light emitting structure layer 113 may emit a third color light. The first color light is green light, the second color light is red light, and the third color light is blue light.

The at least two light emitting structure layers are stacked in a direction perpendicular to the driving substrate 10, so that lights of at least two colors are combined into a mixed light to emit. In some embodiments of the present application, as shown in FIG. 2, the first light emitting structure layer 111, the second light emitting structure layer 112 and the third light emitting structure layer 113 are stacked in a direction perpendicular to the driving substrate 10, so that the green light, red light, and blue light respectively emitted by the first light emitting structure layer 111, the second light emitting structure layer 112 and the third light emitting structure layer 113 are combined into the mixed light and emitted.

The at least two light emitting structure layers are in series connection, so that when the driving substrate 10 independently drives a Micro-LED element 11, the at least two light emitting structure layers in the Micro-LED element 11 synchronously emit light. In some embodiments of the present application, as shown in FIG. 2, the first light emitting structure layer 111, the second light emitting structure layer 112 and the third light emitting structure layer 113 are sequentially connected in series, so that when the driving substrate 10 independently drives the Micro-LED element 11, the first light emitting structure layer 111, the second light emitting structure layer 112 and the third light emitting structure layer 113 in the Micro-LED element 11 synchronously emit light.

The plurality of filter elements 12 and the plurality of Micro-LED elements 11 are correspondingly arranged, and each filter element 12 is at least arranged above a light-emitting surface of the corresponding Micro-LED element 11. The light-emitting surface of the Micro-LED element 11 is the surface, away from a side of the driving substrate 10, of the Micro-LED element 11. The plurality of filter elements 12 include at least two filter elements. Each filter element 12 may transmit one color light from the mixed light emitted by the corresponding Micro-LED element 11 and filter out other color lights. The at least two filter elements may respectively transmit the light of at least two colors and filter out other color lights. The material of the filter element 12 includes organic light-filtering material, or the filter element 12 includes inorganic Bragg reflector, etc.

In some embodiments of the present application, as shown in FIG. 2, the filter elements 12 include a first filter element 121, a second filter element 122 and a third filter element 123. The first filter element 121 may transmit the first color light from the mixed light emitted by the corresponding Micro-LED element 11 and filter out other color lights. The second filter element 122 may transmit the second color light from the mixed light emitted by the corresponding Micro-LED element 11 and filter out other color lights. The third filter element 123 may transmit the third color light from the mixed light emitted by the corresponding Micro-LED element 11 and filter out other color lights. The first color light transmitted by the filter elements 12 is green light, the second color light transmitted by the filter elements 12 is red light, and the third color light transmitted by the filter elements 12 is blue light, so as to perform full-color display with the green light, red light and blue light transmitted by the filter elements 12.

In some embodiments of the present application, the example where the Micro-LED element 11 includes three light emitting structure layers and there are three filter elements 12 of three colors, is used for illustration, but it is not limited thereto. In other embodiments, the Micro-LED element 11 may also include two light emitting structure layers, or four light emitting structure layers, or even more light emitting structure layers. For example, the Micro-LED element 11 may include the first light emitting structure layer capable of emitting the first color light and the second light emitting structure layer capable of emitting the second color light, etc. In other embodiments, the filter elements 12 may also include filter elements of two colors, filter elements of four colors or even filter elements of more colors. For example, the filter elements 12 may include a first filter element that transmits the first color light and filters out other color lights and a second filter element that transmits the second color light and filters out other color lights, etc., which will not be described in detail here.

Because the Micro-LED element 11 includes at least two light emitting structure layers, and lights of at least two colors respectively emitted by the at least two light emitting structure layers may be combined into the mixed light, and the at least two filter elements 12 may transmit lights of at least two colors from the mixed light emitted by the corresponding Micro-LED element 11 and filter out other color lights, so as to perform color display using lights of at least two colors transmitted by the at least two filter elements 12, there is no need to use a wavelength conversion element for wavelength conversion, thereby improving the light emitting efficiency, light emitting brightness and life of the Micro-LED display chip. Furthermore, because the at least two light emitting structure layers are stacked and connected in series, the driving design and manufacturing process of the Micro-LED element 11 may be simplified.

In some embodiments of the present application, in order to improve the light emitting efficiency of the Micro-LED element 11, the arrangement order of the at least two light emitting structure layers in the same Micro-LED element 11 is defined. For example, the at least two light emitting structure layers are arranged sequentially from bottom to top in descending order according to the transmittance of the emitted color light. In some embodiments, the first color light emitted by the first light emitting structure layer 111 is red light, the second color light emitted by the second light emitting structure layer 112 is green light, and the third color light emitted by the third light emitting structure layer 113 is blue light.

In some embodiments of the present application, to achieve the series connection the at least two light emitting structure layers, any two adjacent light emitting structure layers in the same Micro-LED element 11 are electrically connected. The light emitting structure layer farthest from the driving substrate in any one of the Micro-LED elements 11 is electrically connected to the first contact 101 of the driving substrate 10. The light emitting structure layer closest to the driving substrate 10 in any one of the Micro-LED elements 11 is electrically connected to the second contact 102 of the driving substrate 10.

In some embodiments, as shown in FIG. 2, the first light emitting structure layer 111 is electrically connected to the second light emitting structure layer 112, the second light emitting structure layer 112 is electrically connected to the third light emitting structure layer 113, the third light emitting structure layer 113 is electrically connected to the first contact 101 of the driving substrate 10, and the first light emitting structure layer 111 is electrically connected to the second contact 102 of the driving substrate 10.

It should be noted that the driving substrate 10 includes a substrate, a plurality of driving circuits located on one side of the substrate, a plurality of first contacts 101 electrically connected to the plurality of driving circuits and a plurality of second contacts 102 respectively electrically connected to the plurality of driving circuits. The first contacts 101 are located between respective adjacent ones of the Micro-LED elements 11, and the second contacts 102 are located below the Micro-LED elements 11 corresponding to the second contacts 102. Each driving circuit includes a complementary metal-oxide-semiconductor (CMOS) device or a thin-film transistor (TFT) device, etc. Each driving circuit is electrically connected to one first contact 101, and each driving circuit is electrically connected to one second contact 102. Each driving circuit provides a first voltage to the corresponding Micro-LED element 11 through the first contact 101 and provides a second voltage to the corresponding Micro-LED element 11 through the second contact 102, so that the Micro-LED element 11 emits light under the driving of a voltage difference due to the first voltage and the second voltage.

In some embodiments, the light emitting structure layer includes a first doping type semiconductor layer, a light-emitting layer and a second doping type semiconductor layer that are stacked. As shown in FIG. 3, the first light emitting structure layer 111 includes the first doping type semiconductor layer 111a (the first one of a plurality of first doping type semiconductor layers), the first light-emitting layer 111b and the second doping type semiconductor layer 111c (the first one of a plurality of the second doping type semiconductor layers) that are stacked. The second light emitting structure layer 112 includes the first doping type semiconductor layer 112a (the second one of the plurality of the first doping type semiconductor layers), the second light-emitting layer 112b and the second doping type semiconductor layer 112c (the second one of the plurality of the second doping type semiconductor layers) that are stacked. The third light emitting structure layer 113 includes a first doping type semiconductor layer 113a (the third one of the plurality of the first doping type semiconductor layers), a third light-emitting layer 113b and a second doping type semiconductor layer 113c (the third one of the plurality of the second doping type semiconductor layers) that are stacked. The color of the light-emitting layer in the first light emitting structure layer 111, the color of the light-emitting layer in the second light emitting structure layer 112, and the color of the light-emitting layer in the third light emitting structure layer 113 are different, so that the first light emitting structure layer 111, the second light emitting structure layer 112 and the third light emitting structure layer 113 emit different colors of light.

Furthermore, in any two adjacent light emitting structure layers of the same Micro-LED element 11, the first doping type semiconductor layer of one light emitting structure layer is adjacent to and electrically connected to the second doping type semiconductor layer of the other light emitting structure layer, so that any two adjacent light emitting structure layers in the same Micro-LED element 11 are electrically connected. In some embodiments, the first doping type semiconductor layer, the light-emitting layer and the second doping type semiconductor layer in the light emitting structure layer are stacked sequentially in a direction away from or toward the driving substrate 10. In the case where the first doping type semiconductor layer, the light-emitting layer and the second doping type semiconductor layer are stacked sequentially in a direction toward the driving substrate 10, the first doping type semiconductor layer of the light emitting structure layer farthest from the driving substrate in any Micro-LED element 11 is electrically connected to the first contact 101 of the driving substrate 10, so that the light emitting structure layer farthest from the driving substrate in any Micro-LED element 11 is electrically connected to the first contact 101 of the driving substrate 10. The second doping type semiconductor layer of the light emitting structure layer closest to the driving substrate 10 in any Micro-LED element 11 is electrically connected to the second contact 102 of the driving substrate 10, so that the light emitting structure layer closest to the driving substrate 10 in any Micro-LED element 11 is electrically connected to the second contact 102 of the driving substrate 10. The first doping type semiconductor layer and the second doping type semiconductor layer are counter-doped semiconductor layers, i.e., if the first doping type semiconductor layer is an N-type semiconductor layer, the second doping type semiconductor layer is a P-type semiconductor layer, or if the first doping type semiconductor layer is a P-type semiconductor layer, the second doping type semiconductor layer is an N-type semiconductor layer.

Optionally, in some embodiments, as shown in FIG. 3, in the case where the first doping type semiconductor layer, the light-emitting layer, and the second doping type semiconductor layer are stacked sequentially in a direction away from the driving substrate 10, the second doping type semiconductor layer 111c (the first one of the plurality of the second doping type semiconductor layers) of the first light emitting structure layer 111 is adjacent to the first doping type semiconductor layer 112a (the second one of the plurality of the first doping type semiconductor layers)of the second light emitting structure layer 112, and the second doping type semiconductor layer 111c (the first one of a plurality of the second doping type semiconductor layers)of the first light emitting structure layer 111 is electrically connected to the first doping type semiconductor layer 112a (the second one of the plurality of the first doping type semiconductor layers) of the second light emitting structure layer 112. The second doping type semiconductor layer 112c (the second one of the plurality of the second doping type semiconductor layers) of the second light emitting structure layer 112 is electrically connected to the first doping type semiconductor layer 113a (the third one of the plurality of t he first doping type semiconductor layers) of the third light emitting structure layer 113. The second doping type semiconductor layer 113c (the third one of the plurality of the second doping type semiconductor layers) of the third light emitting structure layer 113 is electrically connected to the first contact 101 of the driving substrate 10. The first doping type semiconductor layer 111a (the first one of the plurality of first doping type semiconductor layers) of the first light emitting structure layer 111 is electrically connected to the second contact 102 of the driving substrate 10.

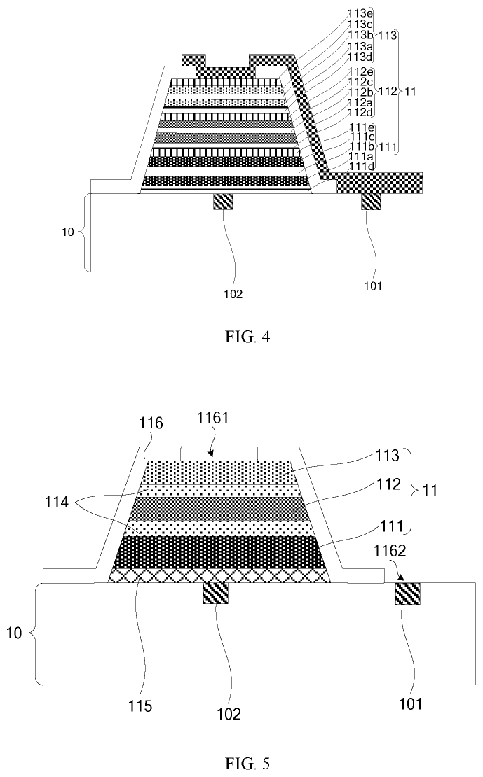

Of course, the present application is not limited thereto. In other embodiments, the light emitting structure layer includes a first electrode layer, the first doping type semiconductor layer, the light-emitting layer, the second doping type semiconductor layer and a second electrode layer that are stacked. As shown in FIG. 4, the first light emitting structure layer 111 includes a first electrode layer 111d (the first one of a plurality of first electrode layers), the first doping type semiconductor layer 111a (the first one of the plurality of first doping type semiconductor layers), the first light-emitting layer 111b, the second doping type semiconductor layer 111c (the first one of the plurality of the second doping type semiconductor layers), and a second electrode layer 111e (the first one of a plurality of second electrode layers) that are stacked. The second light emitting structure layer 112 includes the first electrode layer 112d (the second one of the plurality of the first electrode layers), the first doping type semiconductor layer 112a (the second one of the plurality of the first doping type semiconductor layers), the second light-emitting layer 112b, the second doping type semiconductor layer 112c (the second one of the plurality of the second doping type semiconductor layers), and the second electrode layer 112e (the second one of the second electrode layers) that are stacked. The third light emitting structure layer 113 includes the first electrode layer 113d (the third one of the plurality of first electrode layers), the first doping type semiconductor layer 113a (the third one of the plurality of the first doping type semiconductor layers), a third light-emitting layer 113b, the second doping type semiconductor layer 113c (the third one of the plurality of the second doping type semiconductor layers) and the second electrode layer 113e (the third one of the second electrode layers) that are stacked.

In any two adjacent light emitting structure layers of the same Micro-LED element 11, the first electrode layer of one light emitting structure layer is adjacent to and electrically connected to the second electrode layer of the other one light emitting structure layer, so that any two adjacent light emitting structure layers in the same Micro-LED element 11 are electrically connected. In some embodiments, the first electrode layer, the first doping type semiconductor layer, the light-emitting layer, the second doping type semiconductor layer, and the second electrode layer in the light emitting structure layer may be stacked sequentially in a direction away from or toward the driving substrate 10. In the case where the first electrode layer, the first doping type semiconductor layer, the light-emitting layer, the second doping type semiconductor layer, and the second electrode layer are stacked sequentially in a direction toward the driving substrate 10, the first electrode layer of the light emitting structure layer farthest from the driving substrate 10 in any Micro-LED element 11 is electrically connected to the first contact 101 of the driving substrate 10, so that the light emitting structure layer farthest from the driving substrate in any one Micro-LED element 11 is electrically connected to the first contact 101 of the driving substrate 10. The second electrode layer of the light emitting structure layer closest to the driving substrate 10 in any one Micro-LED element 11 is electrically connected to the second contact 102 of the driving substrate 10, so that the light emitting structure layer closest to the driving substrate 10 in any one Micro-LED element 11 is electrically connected to the second contact 102 of the driving substrate 10.

Optionally, in some embodiments, as shown in FIG. 4, in the case where the first electrode layer, the first doping type semiconductor layer, the light-emitting layer, the second doping type semiconductor layer and the second electrode layer are stacked sequentially in a direction away from the driving substrate 10, the first second electrode layer 111e of the first light emitting structure layer 111 is adjacent to and electrically connected to the second first electrode layer 112d of the second light emitting structure layer 112, the second electrode layer 112e (the second one of the second electrode layers) of the second light emitting structure layer 112 is electrically connected to the first electrode layer 113d (the third one of the plurality of first electrode layers) of the third light emitting structure layer 113. The second electrode layer 113e (the third one of the second electrode layers) of the third light emitting structure layer 113 is electrically connected to the first contact 101 of the driving substrate 10. The first electrode layer 111d (the first one of the plurality of first electrode layers) of the first light emitting structure layer 111 is electrically connected to the second contact 102 of the driving substrate 10.

In some embodiments of the present application, as shown in FIG. 2 and FIG. 3, the Micro-LED element 11 further includes a bonding layer. The bonding layer includes at least one first bonding layer 114 and a second bonding layer 115. The first bonding layer 114 is located between any two adjacent light emitting structure layers. The first bonding layer 114 may bond and electrically connect the adjacent light emitting structure layers. The second bonding layer 115 is located between the light emitting structure layer closest to the driving substrate 10 and the driving substrate 10. The second bonding layer 115 may bond the light emitting structure layer closest to the driving substrate 10 to the driving substrate 10, and electrically connect the light emitting structure layer closest to the driving substrate to the second contact 102 of the driving substrate 10.

In some embodiments, as shown in FIG. 2 and FIG. 3, one first bonding layer 114 is located between the first light emitting structure layer 111 and the second light emitting structure layer 112. This first bonding layer 114 may bond and electrically connect the first light emitting structure layer 111 and the second light emitting structure layer 112. Another first bonding layer 114 is located between the second light emitting structure layer 112 and the third light emitting structure layer 113. This first bonding layer 114 may bond and electrically connect the second light emitting structure layer 112 and the third light emitting structure layer 113. In this way, the first doping type semiconductor layer of one light emitting structure layer is adjacent to and electrically connected to the second doping type semiconductor layer of another light emitting structure layer. The second bonding layer 115 is located between the first light emitting structure layer 111 and the driving substrate 10. The second bonding layer 115 may bond the first light emitting structure layer 111 to the driving substrate 10 and electrically connect the first light emitting structure layer 111 to the second contact 102 of the driving substrate 10. In this embodiment, the bonding layer may be a structure of multiple material layers, and the bonding layer may be the material layer serving as the electrode layer of the light emitting structure layer and material layer serving the bonding function and conductive function. In other embodiments, as shown in FIG. 4, the electrode layers of the light emitting structure layers are designed separately, and the bonding layer is used to bond and electrically connect the electrode layers of the adjacent light emitting structure layers. Of course, the present application is not limited thereto.

In some embodiments of the present application, in order to improve the light emitting efficiency of the Micro-LED element 11, the material of the first bonding layer 114 includes transparent metal oxide material or the combination thereof, such as ITO or IZO, etc. The material of the second bonding layer 115 includes metal material with high reflectivity or a combination thereof, such as Al, Ag, Au, or Cu, Sn, etc., to prevent light from being emitted from the side of the driving substrate 10. In other embodiments, the material of the first electrode layer and the material of the second electrode layer include transparent metal oxide material, and the material of the electrode layer between the light emitting structure layer and the driving substrate 10 is metal material with high reflectivity.

In some embodiments of the present application, as shown in FIG. 5, the Micro-LED display chip further includes a passivation layer 116, and the passivation layer 116 covers the light-emitting surface and the side surfaces of the Micro-LED element 11. Furthermore, the passivation layer 116 includes a plurality of first openings 1161 and a plurality of second openings 1162, the plurality of first openings 1161 may respectively expose the plurality of the first connection portions of the plurality of Micro-LED elements 11, the first connection portion is a portion of the light emitting structure layer that is the farthest from the driving substrate 10 in the Micro-LED element 11 and is electrically connectable to the first contact 101 of the driving substrate 10, and the plurality of first contacts 101 of the driving substrate 10 may be respectively exposed by the plurality of second openings 1162.

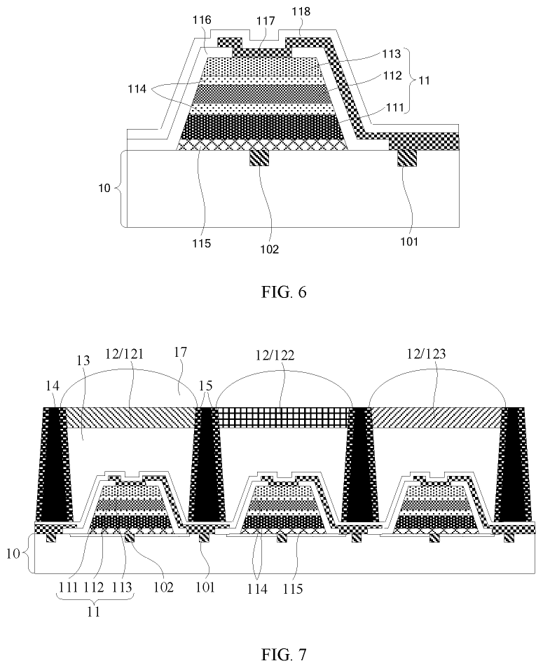

In some embodiments of the present application, as shown in FIG. 6, the Micro-LED display chip 11 further includes a plurality of first electrodes 117, the plurality of first electrodes 117 and the plurality of Micro-LED elements 11 are correspondingly arranged, the first electrode 117 is located on a side, away from the driving substrate 10, of the passivation layer 116 covering the corresponding Micro-LED element 11, and the first electrode 117 fills the first opening 1161 and the second opening 1162 adjacent to the first opening 1161 of the Micro-LED element 11 (corresponding to the first electrode 117), the first electrode 117 may electrically connect the first connection portion of the Micro-LED element 11 (corresponding to the first electrode 117) to the first contact 101 corresponding to the first connection portion. The passivation layer 116 may insulate the first electrode 117 from portions of the Micro-LED element 11 other than the first connection portion.

In some embodiments of the present application, as shown in FIG. 6, the Micro-LED display chip further includes an etch stop layer 118, the etch stop layer 118 is located on a side, away from the driving substrate 10, of the passivation layer 116 or the first electrode 117, the etch stop layer 118 covers the light-emitting surface, the side surfaces of the Micro-LED element 11 and the driving substrate 10 between the Micro-LED elements 11. The etch stop layer 118 protects the Micro-LED element 11 from being damaged by etching in subsequent processes.

In some embodiments of the present application, as shown in FIG. 2, a planarization layer 13 is further provided between the filter element 12 and the corresponding Micro-LED element 11, the planarization layer 13 is used to allow light emitted by the Micro-LED element 11 to pass through. The material of the planarization layer 13 includes transparent adhesive material or transparent inorganic material, so that light emitted by the Micro-LED element 11 may be transmitted by the planarization layer 13 to the maximum extent. The transparent inorganic material may be silicon dioxide or aluminum oxide, etc.

In some embodiments of the present application, as shown in FIG. 2, the Micro-LED display chip further includes a light-blocking wall 14, the light-blocking wall 14 is located between two adjacent Micro-LED elements 11 and two adjacent filter elements 12 corresponding to the two adjacent Micro-LED elements 11, to prevent light crosstalk between the adjacent Micro-LED elements 11. The material of the light-blocking wall 14 may be black light-shielding material, or adhesive material of any color, or inorganic material, etc.

Furthermore, a reflective layer 15 is disposed on the side, towards the Micro-LED element 11, of the light-blocking wall 14, the reflective layer 15 may reflect light emitted by the Micro-LED element 11, so that more light emitted by the Micro-LED element 11 is reflected toward the light-emitting surface of the Micro-LED element 11, thereby improving light emitting efficiency and light emitting brightness of the Micro-LED element 11. The material of the reflective layer 15 may be metal or the combination thereof, such as Al, or Ag, or Au or Cu, or Sn, etc., in addition, the material of the reflective layer 15 may also be organic reflective material, etc.

In some embodiments of the present application, as shown in FIG. 7, the Micro-LED display chip further includes a plurality of micro-lenses 17, the plurality of micro-lenses 17 and the plurality of Micro-LED elements 11 are correspondingly arranged, the micro-lens 17 is used to converge and/or collimate light emitted by the corresponding Micro-LED element 11. It should be noted that the embodiments of the present application are described only by taking the micro-lens 17 being disposed on the side, away from the driving substrate 10, of the filter element 12 as an example, but the present application is not limited thereto, in other embodiments, the micro-lens 17 may also be disposed between the filter element 12 and the Micro-LED element 11, which will not be described again here.

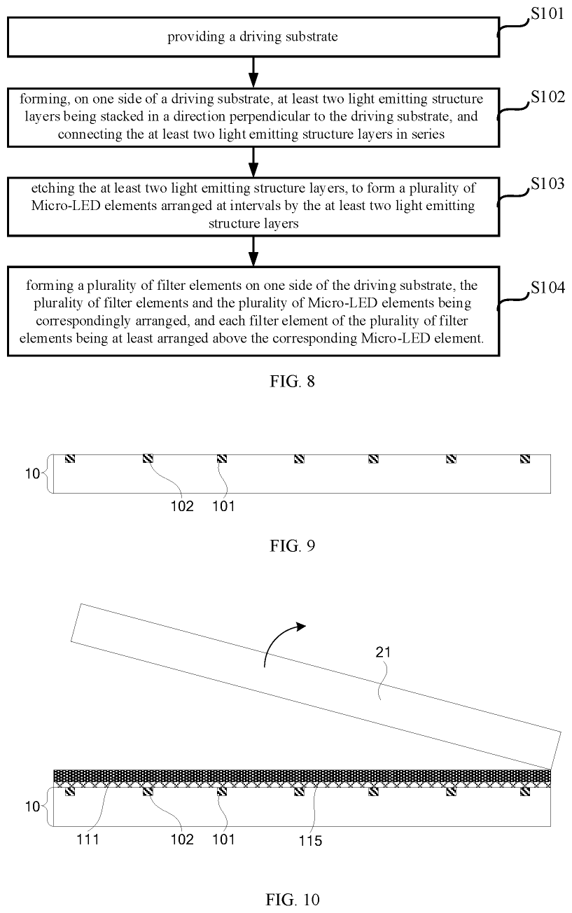

As an optional implementation of the disclosure of the present application, an embodiment of the present application discloses a manufacturing method for a Micro-LED display chip, as shown in FIG. 8, including:

S101: providing a driving substrate.

As shown in FIG. 9, the driving substrate 10 includes a substrate, a plurality of driving circuits, a plurality of first contacts 101 and a plurality of second contacts 102, the plurality of first contacts 101 and the plurality of second contacts 102 are electrically connected to the plurality of driving circuits respectively. The plurality of driving circuits, the plurality of first contacts 101 and the plurality of second contacts 102 are located on one side of the substrate. Each driving circuit includes a CMOS device or a TFT device, etc., and each driving circuit is electrically connected to one first contact 101 and one second contact 102.

S102: forming, on one side of a driving substrate, at least two light emitting structure layers being stacked in a direction perpendicular to the driving substrate, and connecting the at least two light emitting structure layers in series.

The at least two light emitting structure layers can respectively emit light of at least two colors. The at least two light emitting structure layers are stacked in the direction perpendicular to the driving substrate, so that lights of at least two colors may be combined into mixed light and emitted. The at least two light emitting structure layers are connected in series, so that when the driving substrate 10 independently drives the Micro-LED element, the at least two light emitting structure layers in the Micro-LED element synchronously emit light.

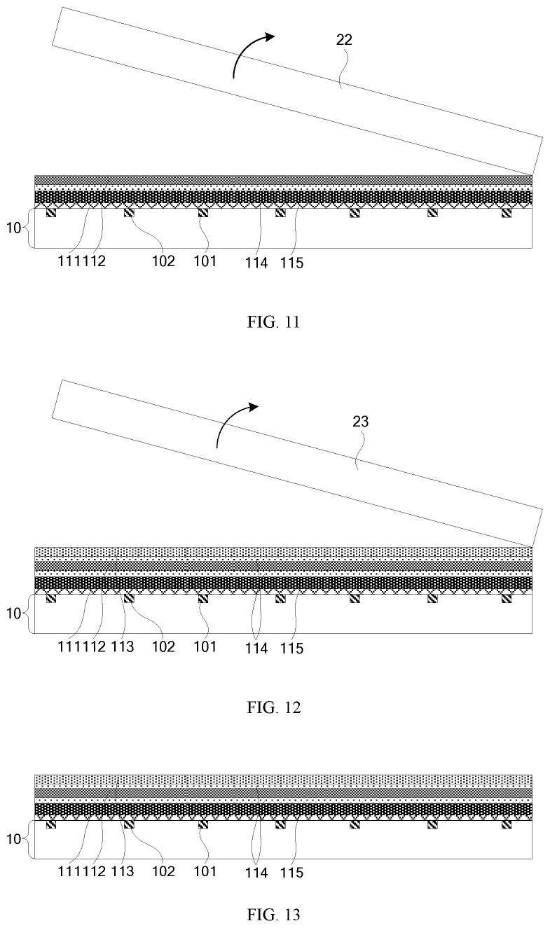

In some embodiments of the present application, the at least two light emitting structure layers may be formed on the driving substrate 10 by bonding. Taking the at least two light emitting structure layers including a first light emitting structure layer, a second light emitting structure layer and a third light emitting structure layer as an example for description. First, a first substrate, a second substrate, and a third substrate are provided, the first light emitting structure layer is disposed on the first substrate, the second light emitting structure layer is disposed on the second substrate, the third light emitting structure layer is disposed on the third substrate, and all of the first light emitting structure layer, the second light emitting structure layer, and the third light emitting structure layer include a first doping type semiconductor layer, a light-emitting layer and a second doping type semiconductor layer that are stacked. Then, as shown in FIG. 10, the first light emitting structure layer 111 is bonded to the driving substrate 10 via a second bonding layer 115, and the second doping type semiconductor layer of the first light emitting structure layer 111 is electrically connected to the corresponding second contact 102 of the driving substrate 10, the first substrate 21 is removed, and the first doping type semiconductor layer of the first light emitting structure layer 111 is exposed. Then, as shown in FIG. 11, the first light emitting structure layer 111 is bonded to the second light emitting structure layer 112 via a first bonding layer 114, so that the first doping type semiconductor layer of the first light emitting structure layer 111 is electrically connected to the second doping type semiconductor layer of the second light emitting structure layer 112, to achieve a series connection between the adjacent light emitting structure layers, the second substrate 22 is removed, and the first doping type semiconductor layer of the second light emitting structure layer 112 is exposed. Then, as shown in FIG. 12, the third light emitting structure layer 113 is bonded to the second light emitting structure layer 112 via another first bonding layer 114, and the first doping type semiconductor layer of the second light emitting structure layer 112 is electrically connected to the second doping type semiconductor layer of the third light emitting structure layer 113, to achieve a series connection between the adjacent light emitting structure layers, the third substrate 23 is removed and the first doping type semiconductor layer of the third light emitting structure layer 113 is exposed, the structure is formed as shown in FIG. 13. Of course, the present application is not limited thereto, in other embodiments, the at least two light emitting structure layers may also be formed directly on the driving substrate 10, which will not be described again here.

In other embodiments, taking the at least two light emitting structure layers including a first light emitting structure layer and a second light emitting structure layer as an example for description. First, the first substrate and the second substrate are provided, the first light emitting structure layer is disposed on the first substrate, the second light emitting structure layer is disposed on the second substrate, and all of the first light emitting structure layer and the second light emitting structure layer include a first doping type semiconductor layer, a light-emitting layer, and a second doping type semiconductor layer that are stacked. Then, the first light emitting structure layer is bonded to the driving substrate via the second bonding layer, and the second doping type semiconductor layer of the first light emitting structure layer is electrically connected to the corresponding second contact of the driving substrate, the first substrate is removed and the first doping type semiconductor layer of the first light emitting structure layer is exposed, the first light emitting structure layer is bonded to the second light emitting structure layer via the first bonding layer, so that the first doping type semiconductor layer of the first light emitting structure layer is electrically connected to the second doping type semiconductor layer of the second light emitting structure layer, to achieve a series connection between the adjacent light emitting structure layers, the second substrate is removed and the first doping type semiconductor layer of the second light emitting structure layer is exposed.

In some embodiments of the present application, connecting the at least two light emitting structure layers in series includes: for any two adjacent light emitting structure layers in the same Micro-LED element 11, the first doping type semiconductor layer of one light emitting structure layer being adjacent to and electrically connected to the second doping type semiconductor layer of another light emitting structure layer, so that the second doping type semiconductor layer of the light emitting structure layer closest to the driving substrate 10 in any one of the Micro-LED elements 11 is electrically connected to the second contact 102 of the driving substrate 10.

Of course, the present application is not limited thereto, in other embodiments, connecting the at least two light emitting structure layers in series includes: for any two adjacent light emitting structure layers in the same Micro-LED element 11, the first electrode layer of one light emitting structure layer being adjacent to and electrically connected to the second electrode layer of another light emitting structure layer, so that the second electrode layer of the light emitting structure layer closest to the driving substrate 10 in any one of Micro-LED elements 11 is electrically connected to the second contact 102 of the driving substrate 10.

In some embodiments of the present application, electrically connecting any two adjacent light emitting structure layers in the same Micro-LED element 11 includes: forming a first bonding layer 114 between any two adjacent light emitting structure layers, where the adjacent light emitting structure layers are bonded and electrically connected via the first bonding layer 114. The electrically connecting the light emitting structure layer closest to the driving substrate 10 in any one of the Micro-LED elements 11 to the second contact 102 of the driving substrate 10 includes: forming a second bonding layer 115 between the light emitting structure layer closest to the driving substrate 10 in any one of the Micro-LED elements 11 and the driving substrate 10, so as to bond the light emitting structure layer closest to the driving substrate 10 in any one of the Micro-LED elements 11 to the driving substrate 10 via the second bonding layer 115 and electrically connect the light emitting structure layer closest to the driving substrate 10 in any one of the Micro-LED elements 11 to the second contact 102 of the driving substrate 10. Of course, the present application is not limited thereto, in other embodiments, referring to FIG. 4, the adjacent light emitting structure layers may also be bonded and electrically connected via the electrode layer, which will not be described again here.

S103: etching the at least two light emitting structure layers, to form a plurality of Micro-LED elements arranged at intervals by the at least two light emitting structure layers.

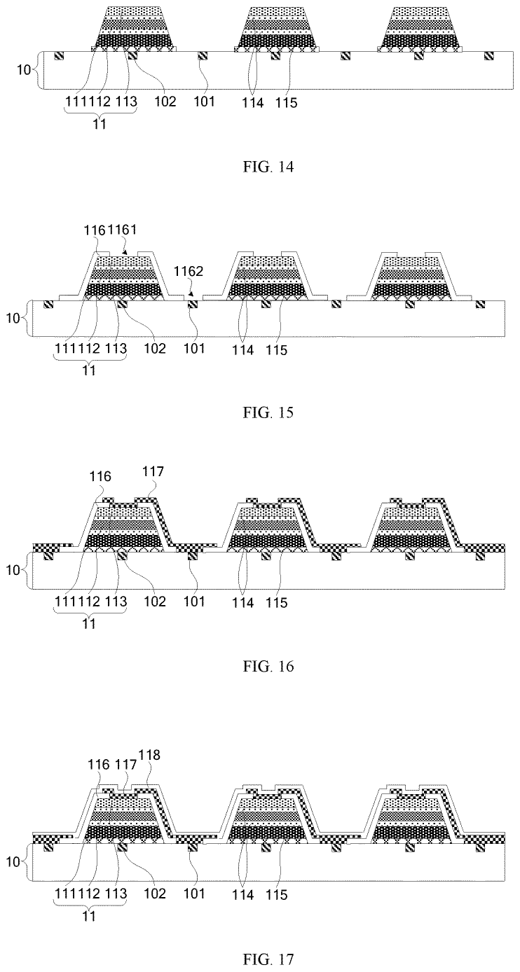

As shown in FIG. 14, the at least two light emitting structure layers are etched, so that the plurality of Micro-LED elements 11 arranged at intervals are formed by the at least two light emitting structure layers. In some embodiments of the present application, after forming a plurality of Micro-LED elements arranged at intervals by the at least two light emitting structure layers, as shown in FIG. 15, a passivation layer 116 covering the light-emitting surface and the side surfaces of the Micro-LED element 11 is formed on one side of the driving substrate 10, and the passivation layer 116 is provided with a plurality of first openings 1161 and a plurality of second openings 1162. The plurality of first openings 1161 may respectively expose a plurality of first connection portions of the plurality of the Micro-LED elements 11, the first connection portion is a portion of the light emitting structure layer that is farthest from the driving substrate in the Micro-LED element 11, and the first connection portion is electrically connected to the first contact 101 of the driving substrate 10, and the plurality of second openings 1162 may respectively expose the plurality of first contacts 101 of the driving substrate 10.

Afterwards, as shown in FIG. 16, a plurality of first electrodes 117 are formed on one side of the driving substrate 10, and the plurality of first electrodes 117 and the plurality of Micro-LED elements 11 are correspondingly arranged, the first electrode 117 is located on the side, away from the driving substrate 10, of the passivation layer 116 covering the corresponding Micro-LED element 11, the first electrode 117 fills the first opening 1161 and the second opening 1162 adjacent to the first opening 1161 of the Micro-LED element 11 (corresponding to the first electrode 117), the first connection portion of the Micro-LED element 11 corresponding to the first electrode 117 is in correspondence with the first contact and electrically connected to the first contact 101 by the first electrode 117, so that the light emitting structure layer farthest from the driving substrate 10 in any one of the Micro-LED elements 11 is electrically connected to the first contact 101 of the driving

### Substrate 10.

Afterwards, as shown in FIG. 17, an etch stop layer 118 is formed on one side of the driving substrate 10, such that the etch stop layer 118 is located on a side, away from the driving substrate 10, of the passivation layer 116 or the first electrode 117, and the light-emitting surface, the side surfaces of the Micro-LED element 11 and the driving substrate 10 between the Micro-LED elements 11 are covered by the etch stop layer 118, so that the etch stop layer 118 protects the Micro-LED element 11 from being etched in subsequent processes.

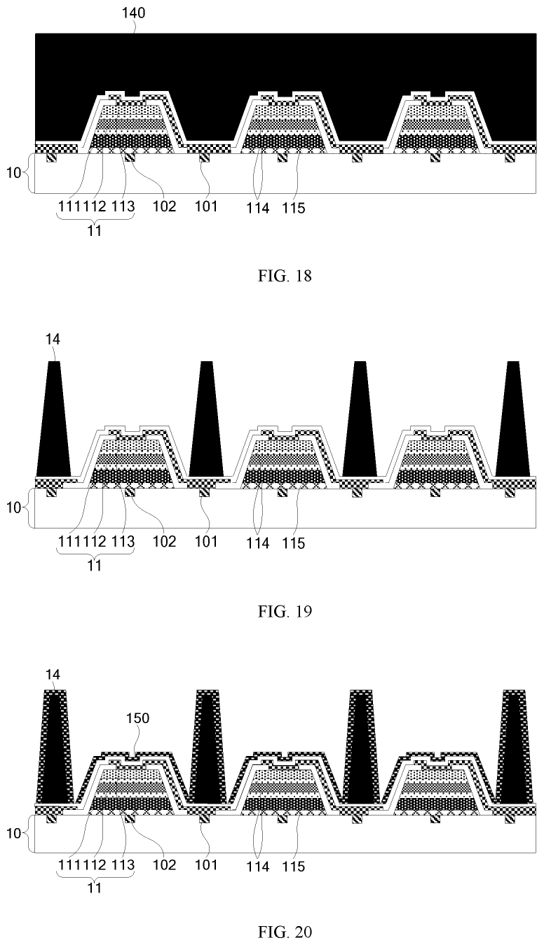

Then, a light-blocking wall is formed on one side of the driving substrate 10, and the light-blocking wall is located between respective adjacent Micro-LED elements 11. As shown in FIG. 18, a light-blocking layer 140 is first formed on one side of the driving substrate 10, the light-blocking layer 140 covers the entire driving substrate 10, then the light-blocking layer 140 is patterned by a photolithography process, or the light-blocking layer 140 is etched by an etching process, so that the light-blocking layer 140 forms the light-blocking wall 14 located between the adjacent Micro-LED elements 11 as shown in FIG. 19.

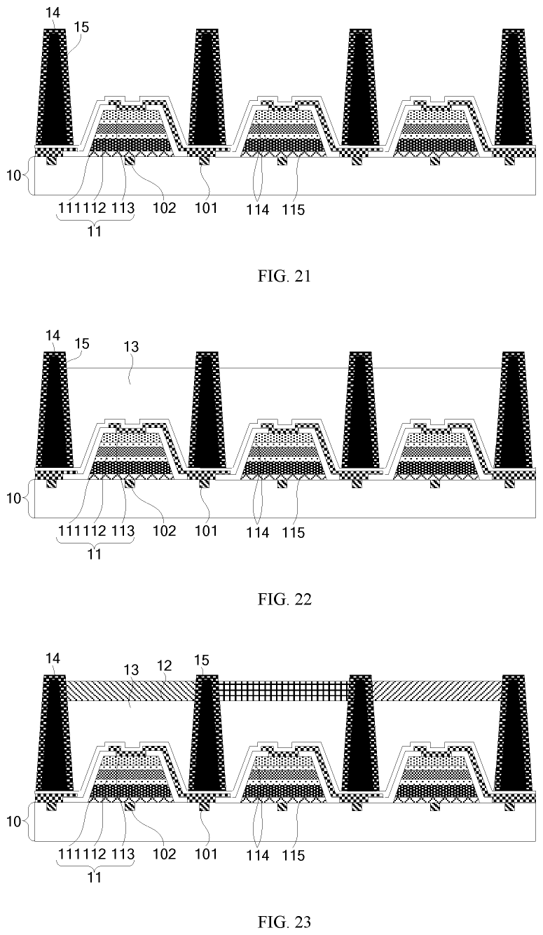

Then, a reflective layer 15 is formed on a side, toward the Micro-LED element 11 of the light-blocking wall 14, the reflective layer 15 may reflect light emitted by the Micro-LED element 11. As shown in FIG. 20, a reflective layer 150 is first formed on one side of the driving substrate 10, the reflective layer 150 covers the entire driving substrate 10, then the reflective layer 150 is etched by the etching process, so that the reflective layer 150 forms the reflective layer 15 wrapping the light-blocking wall 14 as shown in FIG. 21. In some embodiments, after forming the filter element, a planarization process may be performed to remove the reflective layer 15 on the top of the light-blocking wall 14, so that the reflective layer 15 is only located on the side surface, toward the Micro-LED element 11, of the light-blocking wall 14 as shown in FIG. 2.

Then, as shown in FIG. 22, a planarization layer 13 is formed on one side of the driving substrate 10, the planarization layer 13 covers the Micro-LED element 11 and fills the groove surrounded by the light-blocking wall 14, the material of the planarization layer 13 includes transparent photoresist material or transparent inorganic material.

S104: forming a plurality of filter elements on one side of the driving substrate, the plurality of filter elements and the plurality of Micro-LED elements being correspondingly arranged, and each filter element of the plurality of filter elements being at least arranged above the corresponding Micro-LED element.

The plurality of filter elements 12 include at least two filter elements, each filter element 12 may transmit one color light from the mixed light emitted by the corresponding Micro-LED element 11 and filter out other color lights, the at least two filter elements may transmit light of at least two colors and filter out other color lights.

As shown in FIG. 23, the plurality of filter elements 12 are formed on one side the driving substrate 10, and the plurality of filter elements 12 and the plurality of Micro-LED elements 11 are correspondingly arranged, the plurality of filter elements 12 are respectively located in the plurality of grooves surrounded by the light-blocking walls 14, and the plurality of filter elements 12 are located on the side, away from the driving substrate 10, of the planarization layer 13, and the filter element 12 at least covers the light-emitting surface of the corresponding Micro-LED element 11, the plurality of filter elements 12 may transmit light of at least two colors from the mixed light emitted by the plurality of Micro-LED elements 11 and filter out other color lights.

In some embodiments of the present application, referring to FIG. 2, the filter element 12 includes a first filter element 121, a second filter element 122 and a third filter element 123, the first filter element 121 may transmit a first color light from the mixed light emitted by the corresponding Micro-LED element 11 and filter out other color lights, the second filter element 122 may transmit a second color light from the mixed light emitted by the corresponding Micro-LED element 11 and filter out other color lights, the third filter element 123 may transmit a third color light from the mixed light emitted by the corresponding Micro-LED element 11 and filter out other color lights. The first color light, the second color light and the third color light transmitted by the filter element 12 are respectively green light, red light and blue light, so that color display is performed by the green light, red light, and blue light transmitted by the filter elements 12.

In some embodiments of the present application, the description is made only by taking the Micro-LED element 11 including three light emitting structure layers and the filter element 12 including three colors of filter elements as an example, and the application is not limited thereto, in other embodiments, the Micro-LED element 11 may also include two, or four or even more light emitting structure layers, for example, the Micro-LED element 11 may include a first light emitting structure layer capable of emitting a first color light and a second light emitting structure layer capable of emitting a second color light, etc. In other embodiments, the filter element 12 may also include two, or four or even more filter elements with more colors, for example, the filter element 12 may include a first filter element that transmits a first color light and filters out other color lights and a second filter element that transmits a second color light and filters out other color lights, etc., which will not be described again here.

In some embodiments of the present application, as shown in FIG. 7, the manufacturing method for the Micro-LED display chip further includes forming a plurality of micro-lenses 17 on one side of the driving substrate 10, and the plurality of micro-lenses 17 and the plurality of Micro-LED elements 11 are correspondingly arranged, the light emitted by the Micro-LED element 11 corresponding to the micro-lens 17 is converged and/or collimated via the micro-lens 17.

The technical features of the above embodiments may be combined arbitrarily. To keep the description concise, not all possible combinations of the technical features in the above embodiments are described. However, as long as there is no contradiction in the combination of these technical features, it should be considered within the scope of the description.

The above embodiments only express several implementation modes of this specification, and the descriptions thereof are relatively specific and detailed, but they should not be construed as limiting the scope of the invention patent. It should be pointed out that for those of ordinary skill in the art, several variations and improvements can be made without departing from the concept of this specification, and these all fall within the protection scope of this specification. Therefore, the protection scope of the patent of this specification should be based on the appended claims.

What is claimed is:

1. A Micro Light Emitting Diode (Micro-LED) display chip, comprising a driving substrate, a plurality of Micro-LED elements and a plurality of filter elements, the plurality of Micro-LED elements and the plurality of filter elements being located on one side of the driving substrate,
wherein the plurality of Micro-LED elements are arranged at intervals, and each Micro-LED element of the plurality of Micro-LED elements comprises at least two light emitting structure layers, the at least two light emitting structure layers comprise a first light emitting structure layer for emitting a first color light and a second light emitting structure layer for emitting a second color light, the at least two light emitting structure layers are stacked in a direction perpendicular to the driving substrate, and the at least two light emitting structure layers are connected in series, so that when the driving substrate independently drives the Micro-LED element, the at least two light emitting structure layers in the Micro-LED element synchronously emit light, and
the plurality of filter elements and the plurality of Micro-LED elements are correspondingly arranged, each filter element of the plurality of filter elements is at least arranged above a light-emitting surface of the corresponding Micro-LED element, the plurality of filter elements at least comprise a first filter element and a second filter element, the first filter element transmits the first color light and filters out other color lights except the first color light, and the second filter element transmits the second color light and filters out other color lights except the second color light.

2. The Micro-LED display chip according to claim 1, wherein the driving substrate comprises a plurality of first contacts and a plurality of second contacts, the plurality of first contacts are respectively located between respective adjacent ones of the plurality of Micro-LED elements, and the plurality of second contacts are respectively located below the plurality of Micro-LED elements,
in the Micro-LED element, any two adjacent light emitting structure layers of the at least two light emitting structure layers are electrically connected,
in the Micro-LED element, the light emitting structure layer that is the farthest from the driving substrate is in correspondence with the first contact and electrically connected to the first contact corresponding to the light emitting structure layer,
in the Micro-LED element, the light emitting structure layer that is the closest to the driving substrate is in correspondence with the second contact and electrically connected to the second contact corresponding to the light emitting structure layer.

3. The Micro-LED display chip according to claim 2, wherein each light emitting structure layer of the at least two light emitting structure layers comprises a first doping type semiconductor layer, a light-emitting layer, and a second doping type semiconductor layer that are stacked,
in any two adjacent light emitting structure layers of the at least two light emitting structure layers of the Micro-LED element, the first doping type semiconductor layer of one light emitting structure layer is electrically connected to the second doping type semiconductor layer of another light emitting structure layer adjacent to the one light emitting structure layer, to achieve a series connection between the two adjacent light emitting structure layers,
in the Micro-LED element, the first doping type semiconductor layer of the light emitting structure layer that is the farthest from the driving substrate is in correspondence with the first contact and electrically connected to the first contact corresponding to the first doping type semiconductor layer, and the second doping type semiconductor layer of the light emitting structure layer that is the closest to the driving substrate is in correspondence with the second contact and electrically connected to the second contact corresponding to the second doping type semiconductor layer.

4. The Micro-LED display chip according to claim 1, wherein the Micro-LED element further comprises a bonding layer, the bonding layer comprises at least one first bonding layer and one second bonding layer,
the first bonding layer is located between any two adjacent light emitting structure layers of the at least two light emitting structure layers, and the first bonding layer is used for bonding and electrically connecting the two adjacent light emitting structure layers,
the second bonding layer is located between the light emitting structure layer that is the closest to the driving substrate and the driving substrate, and the second bonding layer is used for bonding the light emitting structure layer that is the closest to the driving substrate to the driving substrate and electrically connecting the light emitting structure layer that is the closest to the driving substrate to the second contact of the driving substrate.

5. The Micro-LED display chip according to claim 4, wherein a material of the first bonding layer comprises a transparent conductive material, so as to allow light emitted by the at least two light emitting structure layers to pass through, and a material of the second bonding layer comprises a reflective conductive material to reflect light emitted by the at least two light emitting structure layers.

6. The Micro-LED display chip according to claim 1, further comprising a passivation layer, wherein a light-emitting surface and a side surface of the Micro-LED element are covered by the passivation layer,
the passivation layer comprises a plurality of first openings and a plurality of second openings, the plurality of first openings respectively expose a plurality of first connection portions of the plurality of Micro-LED elements, the first connection portion is a light emitting structure layer that is the farthest from the driving substrate in the Micro-LED element, and the plurality of second openings respectively expose the plurality of first contacts of the driving substrate.

7. The Micro-LED display chip according to claim 6, further comprising a plurality of first electrodes,
wherein the plurality of first electrodes and the plurality of Micro-LED elements are correspondingly arranged, and each first electrode of the plurality of first electrodes is used to electrically connect the first connection portion of the Micro-LED element to the first contact corresponding to the Micro-LED element through the first opening and the second opening corresponding to the Micro-LED element.

8. The Micro-LED display chip according to claim 7, further comprising an etch stop layer, wherein the etch stop layer is located on a side, away from the driving substrate, of the passivation layer or the first electrode, and the light-emitting surface and the side surface of the Micro-LED element are covered by the etch stop layer.

9. The Micro-LED display chip according to claim 1, further comprising a light-blocking wall, wherein the light-blocking wall is located between two adjacent Micro-LED elements of the plurality of Micro-LED elements, a reflective layer is disposed on a side wall of the light-blocking wall, and the reflective layer reflects light emitted by the Micro-LED element.

10. The Micro-LED display chip according to claim 1, wherein a planarization layer is located between the filter element and the Micro-LED element corresponding to the filter element, and light emitted by the Micro-LED element is allowed to pass through the planarization layer.

11. The Micro-LED display chip according to claim 1, wherein the at least two light emitting structure layers further comprise a third light emitting structure layer capable of emitting a third color light, and the plurality of filter elements further comprise a third filter element, the third filter element transmits the third color light and filters out other color lights except the third color light.

12. The Micro-LED display chip according to claim 1, further comprising a plurality of micro-lenses, the plurality of micro-lenses and the plurality of Micro-LED elements are correspondingly arranged, and each micro-lens of the plurality of micro-lenses is used for converging and/or collimating light emitted by the corresponding Micro-LED element.

13. A manufacturing method for a Micro-LED display chip, comprising:
forming, on one side of a driving substrate, at least two light emitting structure layers being stacked in a direction perpendicular to the driving substrate, connecting the at least two light emitting structure layers in series, wherein the at least two light emitting structure layers comprise a first light emitting structure layer for emitting a first color light and a second light emitting structure layer for emitting a second color light;
etching the at least two light emitting structure layers, to form a plurality of Micro-LED elements arranged at intervals by the at least two light emitting structure layers, when the driving substrate independently drives each Micro-LED element of the plurality of Micro-LED elements, the at least two light emitting structure layers in the Micro-LED element synchronously emit light; and
forming a plurality of filter elements on one side of the driving substrate, wherein the plurality of filter elements and the plurality of Micro-LED elements are correspondingly arranged, and each filter element of the plurality of filter elements is at least arranged above the corresponding Micro-LED element, the plurality of filter elements at least comprise a first filter element and a second filter element, the first filter element transmits the first color light and filters out other color lights except the first color light, and the second filter element transmits the second color light and filters out other color lights except the second color light.

14. The manufacturing method according to claim 13, the forming, on one side of a driving substrate, at least two light emitting structure layers being stacked in a direction perpendicular to the driving substrate comprising:
disposing the first light emitting structure layer on a first substrate, wherein the first light emitting structure layer comprises a first doping type semiconductor layer, a light-emitting layer, and a second doping type semiconductor layer that are stacked;
disposing the second light emitting structure layer on a second substrate, wherein the second light emitting structure layer comprises a first doping type semiconductor layer, a light-emitting layer, and a second doping type semiconductor layer that are stacked;
bonding the first light emitting structure layer to the driving substrate via a second bonding layer, and electrically connecting the second doping type semiconductor layer of the first light emitting structure layer to the second contact corresponding to the driving substrate;
removing the first substrate and exposing the first doping type semiconductor layer of the first light emitting structure layer;
bonding the first light emitting structure layer to the second light emitting structure layer via a first bonding layer, such that the first doping type semiconductor layer of the first light emitting structure layer is electrically connected to the second doping type semiconductor layer of the second light emitting structure layer, to achieve a series connection between the two adjacent light emitting structure layers of the at least two light emitting structure layers; and
removing the second substrate and exposing the first doping type semiconductor layer of the second light emitting structure layer.

15. The manufacturing method according to claim 14, further comprising:
disposing a third light emitting structure layer for emitting a third color light on a third substrate, wherein the third light emitting structure layer comprises a first doping type semiconductor layer, a light-emitting layer, and a second doping type semiconductor layer that are stacked;
bonding the third light emitting structure layer to the second light emitting structure layer via the first bonding layer, and electrically connecting the first doping type semiconductor layer of the second light emitting structure layer to the second doping type semiconductor layer of the third light emitting structure layer, to achieve a series connection between the two adjacent light emitting structure layers of the at least two light emitting structure layers; and
removing the third substrate and exposing the first doping type semiconductor layer of the third light emitting structure layer,
wherein the plurality of filter elements further comprise a third filter element, the third filter element transmits the third color light and filters out other color lights except the third color light.

16. The manufacturing method according to claim 13, after the etching the at least two light emitting structure layers to form a plurality of Micro-LED elements arranged at intervals by the at least two light emitting structure layers, the manufacturing method further comprising:
forming, on one side of the driving substrate, a passivation layer covering a light-emitting surface and a side surface of the Micro-LED element, wherein the passivation layer is provided with a plurality of first openings and a plurality of second openings, the plurality of first openings respectively expose a plurality of first connection portions of the plurality of Micro-LED elements, the first connection portion is the light emitting structure layer that is the farthest from the driving substrate in the Micro-LED element, the plurality of second openings respectively expose a plurality of first contacts of the driving substrate; and
forming a plurality of first electrodes on one side of the driving substrate, wherein the plurality of first electrodes and the plurality of Micro-LED elements are correspondingly arranged, such that each first electrode of the plurality of first electrodes is used to electrically connect the first connection portion of the Micro-LED element to the first contact corresponding to the Micro-LED element through the first opening and the second opening corresponding to the Micro-LED element.

17. The manufacturing method according to claim 16, further comprising:
forming an etch stop layer on one side of the driving substrate, such that the etch stop layer is located on a side, away from the driving substrate, of the passivation layer or the first electrode, and the light-emitting surface and the side surface of the Micro-LED element are covered by the etch stop layer.

18. The manufacturing method according to claim 13, before the forming the plurality of filter elements on one side of the driving substrate, the manufacturing method further comprising:
forming a light-blocking wall on one side of the driving substrate, wherein the light-blocking wall is located between respective adjacent ones of the plurality of Micro-LED elements; and
forming a reflective layer at a side wall, towards the Micro-LED element, of the light-blocking wall, wherein the reflective layer reflects light emitted by the Micro-LED element.

19. The manufacturing method according to claim 18, further comprising:
forming a planarization layer on one side of the driving substrate, such that the planarization layer covers the Micro-LED element and fills a groove surrounded by the light-blocking wall, and light emitted by the Micro-LED element is allowed to pass through the planarization layer.

20. The manufacturing method according to claim 13, further comprising:
forming a plurality of micro-lenses on one side of the driving substrate, wherein the plurality of Micro-LED elements and the plurality of micro-lenses are correspondingly arranged, and each micro-lens of the plurality of micro-lenses converges and/or collimates light emitted by the corresponding Micro-LED element.
